(19) United States
(12) Patent Application Publication
(10) Pub. No.: US 2024/0211648 A1
(43) Pub. Date: Jun. 27, 2024

(54) SYSTEM PLATFORM FOR EVALUATION AND RESEARCH AND DEVELOPMENT OF VIBRATION AND NOISE REDUCTION TECHNOLOGY FOR RAIL TRANSIT

(71) Applicant: BEIJING JIAOTONG UNIVERSITY, BEIJING (CN)

(72) Inventors: BOWEN HOU, BEIJING (CN); XINGYU CHEN, BEIJING (CN); LIANG GAO, BEIJING (CN); HUI YIN, BEIJING (CN); DI WANG, BEIJING (CN); BINGBING WANG, BEIJING (CN); LINCHUAN QIAO, BEIJING (CN); MENGFEI DU, BEIJING (CN); YUNWEI ZHU, BEIJING (CN); YI XIANG, BEIJING (CN)

(21) Appl. No.: 18/329,560

(22) Filed: Jun. 5, 2023

(30) Foreign Application Priority Data
Dec. 27, 2022 (CN) 202211683388.0

(51) Int. Cl. G06F 30/15; H04R 3/00

(52) U.S. Cl. CPC G06F 30/15; H04R 3/005

(57) ABSTRACT

Disclosed is a system platform for evaluation and research and development of vibration and noise reduction technology for rail transit, including a hemi-anechoic chamber, a run-through tunnel, a simulated track, and a reduced-scale train running on the simulated track. The run-through tunnel is enclosed by sound insulation and absorption boards. The side wall of the hemi-anechoic chamber is provided with a door opening; the exit of the run-through tunnel communicates with the door opening, and the entrance of the run-through tunnel is arranged at the end part, away from the hemi-anechoic chamber, of the run-through tunnel. The simulated track is continuously arranged into the hemi-anechoic chamber from the outside of the run-through tunnel via the entrance, the exit and the door opening.

### CROSS-REFERENCE TO RELATED APPLICATION

This patent application claims the benefit and priority of Chinese Patent Application No. 202211683388.0, filed with the China National Intellectual Property Administration on Dec. 27, 2022, the disclosure of which is incorporated by reference herein in its entirety as part of the present application.

### TECHNICAL FIELD

The present disclosure relates to the technical field of rail transit, in particular to a system platform for evaluation and research and development of vibration and noise reduction technology for rail transit.

### BACKGROUND

Rail transit is a type of vehicle or transportation system that requires operating vehicles to travel on a particular track. The most typical rail transit is the railway system composed of traditional trains and standard railways. With the rapid development of social economy, in addition to the requirements for speed increase, people's requirements for railway transportation in ride comfort are getting higher and higher. Meanwhile, with the continuous increase of railway mileage, the influence of railway transportation on the environment is also growing, and the most prominent problem is the environmental vibration and noise generated during railway operation. Therefore, in order to improve passenger comfort and reduce the environmental vibration and noise generated during train operation, the evaluation and research and development of vibration and noise reduction technology have become an increasingly urgent need.

In the prior art, a method for evaluating vibration and noise reduction technology refers to field test of a track experimental section after taking vibration reduction and noise reduction measures. According to the method, line structures before and after vibration and noise reduction measures are taken are required to be constructed on site. When the train passes through this section of the line, the vibration and noise reduction amount of the taken vibration and noise reduction measures are evaluated by means of on-site actual test. However, as the line structures before and after taking vibration and noise reduction measures are required to be constructed on site in the early stage of this method, the consumed time is long, and the experimental cost is high; and as the track structure form is hard to change after being determined, the difficulty of experiment is greatly increased.

Another method for evaluating vibration and noise reduction technology in the prior art is a reduced-scale model experiment. In this method, by constructing a scaled-down train and a track structure, and comparing the trains when passing through the line structures before and after taking vibration and noise reduction measures, the vibration and noise reduction effect on a reduced-scale model is evaluated; and finally, the vibration and noise reduction amount of the taken vibration and noise reduction measures on the actual line structure is evaluated according to a conversion method of a certain proportion. Although the method solves the shortcomings of high cost and difficult change of track structure form in the track experimental section, due to the reduction in dimension, the requirements for vibration and noise isolation of external environment are higher, and the test process is greatly influenced by the outside world. The main shortcomings of the reduced-scale model experiment are that a hemi-free field environment required for testing the wheel-rail radiation noise cannot be provided for the running train, and the actual amplitude of wheel-rail vibration and rolling radiation noise cannot be completely tested, leading to large error of the test results.

The existing anechoic chamber is mainly used for acoustic experiment and noise test, which can isolate the influence of external noise and vibration, thereby accurately testing the noise level of automobiles, audio products, electronic products, musical instruments and other products. For example, an acoustic laboratory for vibration and noise testing of a vehicle power train system is disclosed in the Chinese Patent with Application Publication No. CN110469148A, which is limited to test the vehicular drivetrain in an acoustic laboratory. For another example, a micro-vibration laboratory for spacecraft interference sources is disclosed in the Chinese patent with Publication No. CN104453288B, which is also limited to arrange a spacecraft in a laboratory for testing. In the prior art, there has not been related technology to combine the anechoic chamber with rail transit lines and trains.

### SUMMARY

An objective of the present disclosure is to provide a system platform for evaluation and research and development of vibration and noise reduction technology for rail transit, so as to solve the problems in the prior art. By connecting a hemi-anechoic chamber with a run-through tunnel, and providing a simulated track for the running of a reduced-scale train in the run-through tunnel, a hemi-free field environment required for testing wheel-rail radiation noise can be provided for the running reduced-scale train, the influence of external vibration and noise can be isolated, and the actual amplitude of wheel-rail radiation noise can be completely tested, thereby providing a platform for the evaluation and research and development of vibration and noise reduction technology for the rail transit.

In order to achieve the above object, the present disclosure provides the following solution:

A system platform for evaluation and research and development of vibration and noise reduction technology for rail transit provided by the present disclosure includes a hemi-anechoic chamber, a run-through tunnel, a simulated track, and a reduced-scale train running on the simulated track. The run-through tunnel is enclosed by sound insulation and absorption boards. The side wall of the hemi-anechoic chamber is provided with a door opening, the exit of the run-through tunnel communicates with the door opening, and the entrance of the run-through tunnel is arranged at the end part, away from the hemi-anechoic chamber, of the run-through tunnel. The simulated track is continuously arranged into the hemi-anechoic chamber from the outside of the run-through tunnel via the entrance, the exit and the door opening. A simulated hemi-free space is provided in the hemi-anechoic chamber, and the vibration and noise of the reduced-scale train when passing through the simulated hemi-free space are tested.

Preferably, the hemi-anechoic chamber and the run-through tunnel are both of a rectangular structure. The run-through tunnel is arranged on the short-edge side at the corner of the hemi-anechoic chamber, and the simulated track is arranged in a diagonal direction of the hemi-anechoic chamber, or the run-through tunnel is arranged on the short-edge side of the hemi-anechoic chamber, and the simulated track is arranged in a long edge direction of the hemi-anechoic chamber.

Preferably, the length, width and height of the run-through tunnel are all smaller than those of the hemi-anechoic chamber.

Preferably, a detachable wall is provided at the door opening, and the detachable wall has the same structure as the original wall of the hemi-anechoic chamber. Wheels are arranged at the bottom of the detachable wall. A detachable structure is adopted for the simulated track at the door opening; and the original function of the hemi-anechoic chamber can be recovered by disassembling the simulated track and installing the detachable wall.

Preferably, the hemi-anechoic chamber includes an inner suite and an outer suite without rigid connection. A rubber vibration isolator is provided between the inner suite and the outer suite, and the rubber vibration isolator is located under the floor of the inner suite for supporting the inner suite.

Preferably, the inner suite is formed by splicing metal sound insulation and absorption modules, and the metal sound insulation and absorption modules constitute a self-supporting structure of the inner suite. The metal sound insulation and absorption modules each include a first wedge and a connecting structure for connecting the first wedge, and the outer suite is formed by splicing low-frequency sound absorption and insulation boards.

Preferably, the side face of the hemi-anechoic chamber is provided with a sound insulation door, and the sound insulation door is far away from the door opening and close to the tail end of the simulated track.

Preferably, the sound insulation door includes an outer fireproof sound insulation door and an inner sound insulation sound absorption door. The fireproof sound insulation door is opened from inside to outside, the sound insulation and absorption door is opened from outside to inside, and a second wedge is arranged on the inner surface of the sound insulation and absorption door. A cavity between the second wedge and the sound insulation and absorption door is decorated by a skeleton and a sound absorption board, so as to form an integrated sound insulation and absorption door.

Preferably, the sound insulation and absorption door is provided with a bushing at a door shaft, and the bushing is rotationally arranged on a bushing support. The top end of the bushing support is fixed to a wall through a cantilever, and the bottom end of the bushing support is fixed to the ground. The second wedge has the same shape as the first wedge, and when the sound insulation and absorption door is closed, the second wedge and the first wedge are flush with each other without interfering.

Preferably, the system platform includes an air conditioning and ventilation module. The air conditioning and ventilation module is provided with two stages of mufflers, including a first-stage muffler installed in an air conditioning room, and a second-stage muffler installed at the position where an air duct enters the anechoic chamber.

Compared with the prior art, the present disclosure has the following technical effects:
(1) In accordance with the present disclosure, by connecting a hemi-anechoic chamber with a run-through tunnel, and providing a simulated track for the running of a reduced-scale train in the run-through tunnel, the combination of the simulated track and the hemi-anechoic chamber can be achieved, a hemi-free field environment required for testing wheel-rail radiation noise can be provided for the running reduced-scale train, the influence of external vibration and noise can be isolated, and the actual amplitude of the wheel-rail vibration and rolling radiation noise of the reduced-scale train-rail model in a running state can be completely and accurately tested, thus providing a platform for the evaluation and research and development of vibration and noise reduction technology for the rail transit.
(2) The simulated track is arranged in a diagonal direction of the hemi-anechoic chamber, thus maximizing the internal space of the hemi-anechoic chamber, extending the laying length of the simulated track, and ensuring the maximum space utilization rate in a limited space.
(3) In the present disclosure, a detachable wall is arranged at the door opening where the hemi-anechoic chamber communicates with the run-through tunnel; meanwhile, the simulated track at the door opening is a detachable structure, and the door opening can be opened or closed by using the detachable wall. The door opening can be opened during related experiments of the rail transit, thus facilitating the passing of the reduced-scale train, and the door opening can be closed during the testing inside the hemi-anechoic chamber, thus not affecting the sound absorption and insulation of the hemi-anechoic chamber. In addition, wheels can be arranged at the bottom of the detachable wall to facilitate the movement of the detachable wall, i.e., facilitating the opening and closing of the door opening.
(4) The hemi-anechoic chamber includes an inner suite and an outer suite without rigid connection, and a rubber vibration isolator is supported under the floor of the inner suite, thus effectively isolating the external solid sound transmission and further improving the accuracy of the test.
(5) The side face of the hemi-anechoic chamber is provided with a sound insulation door, which is opened when needed to facilitate the passing, and is closed during the test to effectively isolate the noise. Meanwhile, the sound insulation door is arranged far away from the door opening and close to the tail end of the simulated track, so as to reduce the influence of the sound insulation door on the test process to the greatest extent.

### BRIEF DESCRIPTION OF THE DRAWINGS

To describe the technical solutions in the embodiments of the present disclosure or in the prior art more clearly, the following briefly introduces the accompanying drawings required for describing the embodiments. Apparently, the accompanying drawings in the following description show merely some embodiments of the present disclosure, and those of ordinary skill in the art may still derive other drawings from these accompanying drawings without creative efforts.

FIG. 1 is a top view of an overall structure in accordance with the present disclosure;

FIG. 2 is a schematic diagram of each track structure in FIG. 1;

FIG. 3 is a schematic diagram of a P-P structure in FIG. 1;

FIG. 4 is a schematic diagram of a N-N structure in FIG. 1;

FIG. 5 is a schematic diagram of an M-M structure in FIG. 1;

FIG. 6 is a schematic diagram of a structure at Q in FIG. 1;

FIG. 7 is an arrangement diagram of a first wedge on an AB face in FIG. 1;

FIG. 8 is an arrangement diagram of a first wedge on a BC face in FIG. 1;

FIG. 9 is an arrangement diagram of a first wedge on a CD face in FIG. 1;

FIG. 10 is an arrangement diagram of a first wedge on a DA face in FIG. 1;

FIG. 11 is an arrangement diagram of a first wedge on the top face of a hemi-anechoic chamber in accordance with the present disclosure.

In the drawings: 1—hemi-anechoic chamber; 11—outer suite; 12—inner suite; 121—first wedge; 13—sound insulation door; 131—fireproof sound insulation door; 132—sound insulation and absorption door; 133—bushing support; 14—detachable wall; 141—second wedge; 15—door opening; 16—light box; 2—run-through tunnel; 3—simulated track; 31—steel rail; 32—reduced-scale train; 33—bearing; 4—arc-shaped rail; 5—straight rail.

### DETAILED DESCRIPTION OF THE EMBODIMENTS

The following clearly and completely describes the technical solutions in the embodiments of the present disclosure with reference to the accompanying drawings in the embodiments of the present disclosure. Apparently, the described embodiments are merely a part rather than all of the embodiments of the present disclosure. All other embodiments obtained by a person of ordinary skill in the art based on the embodiments of the present disclosure without creative efforts shall fall within the protection scope of the present disclosure.

An objective of the present disclosure is to provide a system platform for evaluation and research and development of vibration and noise reduction technology for rail transit, so as to solve the problems in the prior art. By connecting a hemi-anechoic chamber with a run-through tunnel, and providing a simulated track for the running of a reduced-scale train in the run-through tunnel, a hemi-free field environment required for testing wheel-rail radiation noise can be provided for the running reduced-scale train, the influence of external vibration and noise can be isolated, and the actual amplitude of wheel-rail radiation noise can be completely tested, thereby providing a platform for the evaluation and research and development of vibration and noise reduction technology for the rail transit.

To make the objectives, features and advantages of the present disclosure more apparently and understandably, the following further describes the present disclosure in detail with reference to the accompanying drawings and the specific embodiments.

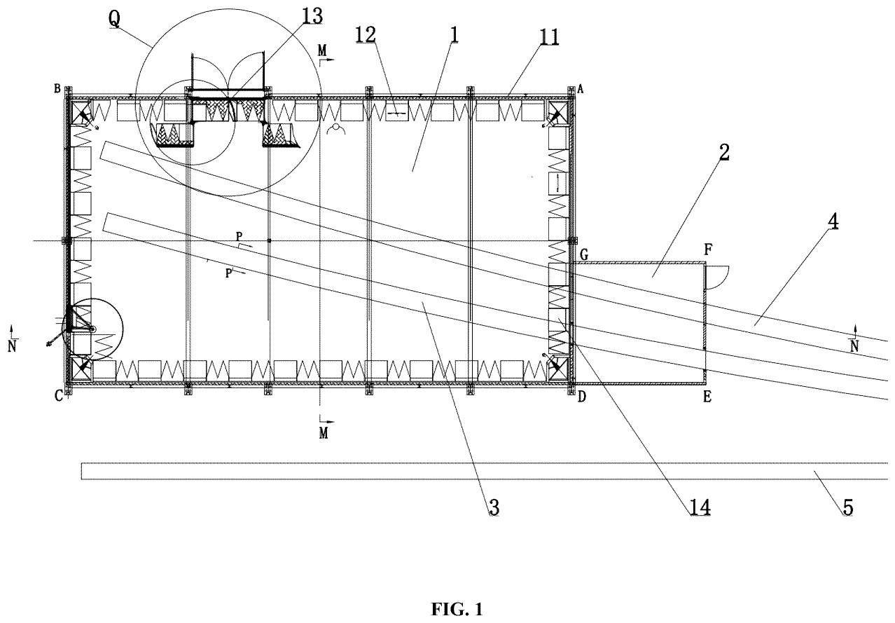

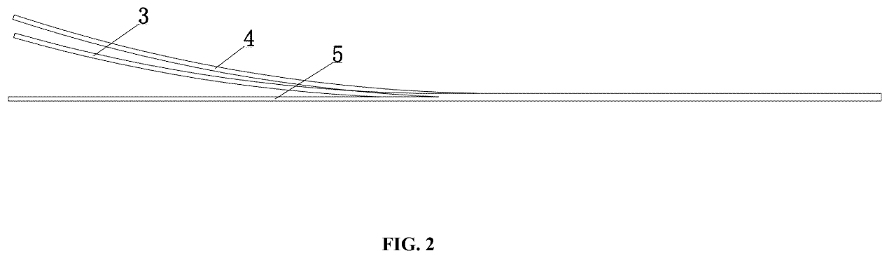

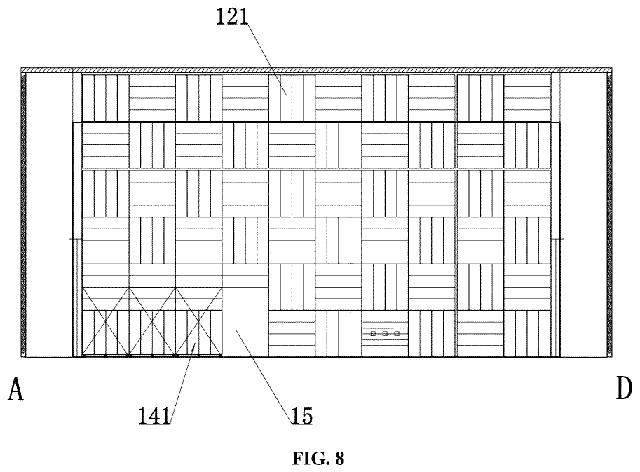

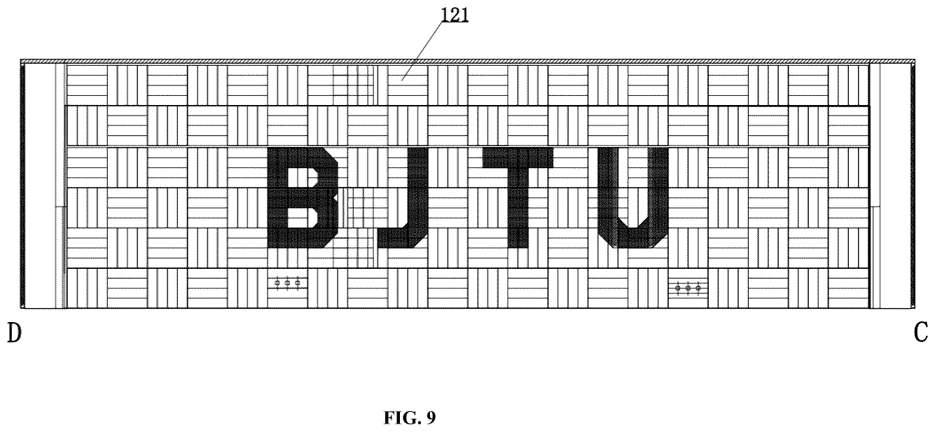

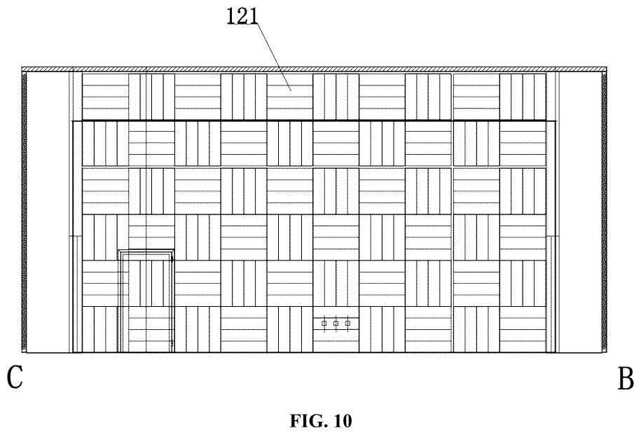

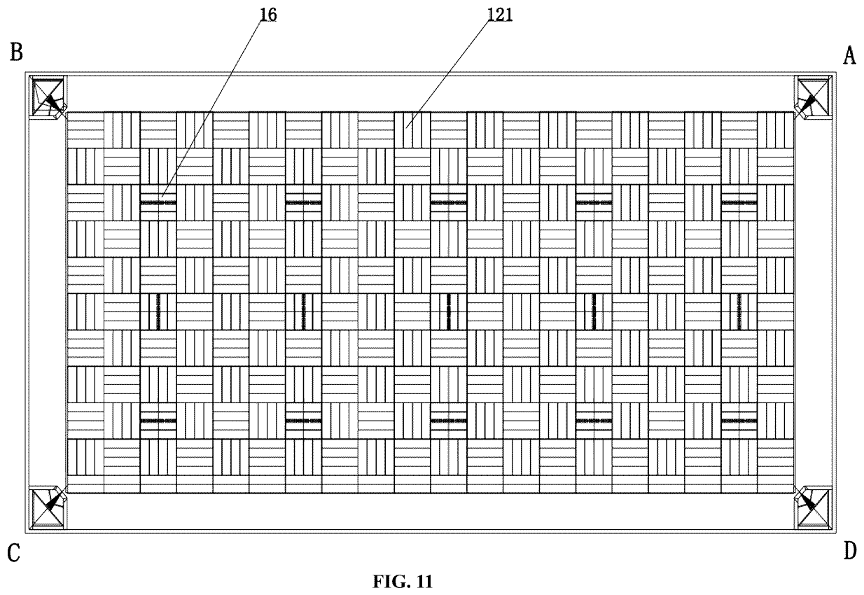

As shown from FIG. 1 to FIG. 11, a system platform for evaluation and research and development of vibration and noise reduction technology for rail transit is provided, which includes a hemi-anechoic chamber 1, a run-through tunnel 2, and a simulated track 3. The hemi-anechoic chamber 1 can be constructed by using the prior art, is provided with a sound insulation and absorption material except for the ground, and is an anechoic chamber with the floor as the reflecting surface. The run-through tunnel 2 is enclosed by sound insulation and absorption boards, and the specific materials can be selected according to the actual situation, which mainly plays a role of sound insulation and noise elimination. The run-through tunnel is equivalent to a large muffler, which is configured to reduce the external ventilation noise and to provide a space for the reduced-scale train 32 to pass through. The side wall of the hemi-anechoic chamber 1 is provided with a door opening 15, the exit of the run-through tunnel 2 communicates with the door opening 15, and the entrance of the run-through tunnel 2 is arranged at the end part, away from the hemi-anechoic chamber 1, of the run-through tunnel 2, that is, the run-through tunnel 2 and the hemi-anechoic chamber 1 form a communication structure through the door opening 15. The simulated track 3 is continuously arranged into the hemi-anechoic chamber 1 from the outside of the run-through tunnel 2 via the entrance and exit of the run-through tunnel 2 and then via the door opening 15, and is used for running the reduced-scale train 32. The simulated track 3 may also have other deformation structures, for example, the simulated track 3 can be arranged as another arc-shaped rail 4 by changing the radian, or a straight rail 5 can be provided as required. Certainly, the straight rail 5 can lead into the hemi-anechoic chamber 1 or not. Thereby, the reduced-scale train 32 can start and accelerate at the outside simulated track 3 part, and reach a set speed for related tests after entering the hemi-anechoic chamber 1, and finally decelerate and stop in the hemi-anechoic chamber 1. By connecting the run-through tunnel 2 to the door opening 15 of the hemi-anechoic chamber 1, the situation that accurate test data cannot be obtained due to the weakening of the sound insulation and noise elimination effect of the hemi-anechoic chamber 1 caused by the direct providing of the door opening 15 on the hemi-anechoic chamber 1 can be avoided. Therefore, by connecting the hemi-anechoic chamber 1 to the run-through tunnel 2, and providing the simulated track 3 for the running of the reduced-scale train 32 in the run-through tunnel 2, the simulated track 3 passes through a simulated hemi-free space in the hemi-anechoic chamber 1, and the vibration and noise of the reduced-scale train when passing through the simulated hemi-free space are tested. The simulated hemi-free space refers to that the hemi-anechoic chamber 1 also has a certain acoustic reflection at the boundary, which can be regarded as a standard hemi-free field in a hemi-ellipsoidal space with the center of the hemi-anechoic chamber 1 as the origin, thus providing a hemi-free field environment required for testing the wheel-rail radiation noise for the running reduced-scale train 32. In a case that the testing range exceeds this range, there may be the problem of superposition of reflected waves, leading to distortion of the results. Therefore, the formation of the hemi-free field environment may isolate the influence of external vibration and noise, and the actual amplitude of the wheel-rail vibration and rolling radiation noise of a reduced-scale train-rail model in a running state can be completely and accurately tested, thus providing a platform for the evaluation and research and development of vibration reduction and noise reduction technology for rail transit.

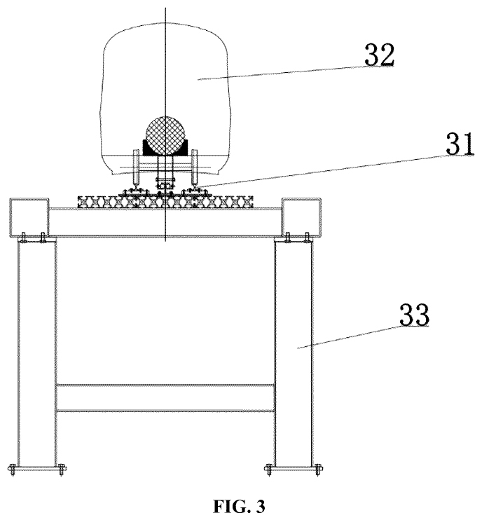

As shown in FIG. 3, the simulated track 3 may include bearings 33 which are continuously provided as a supporting structure, steel rails 13 arranged in parallel are erected on the bearings 33, and the reduced-scale train 32 runs on the steel rails 13. In order to facilitate the adjustment of the direction of the steel rails 13 or facilitate the installation and removal of parts of the steel rails 13, the bearings 33 may be fixed to the ground in a detachable manner.

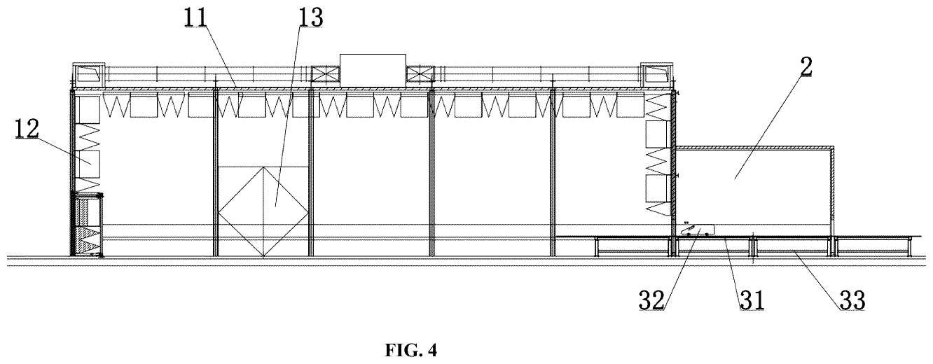

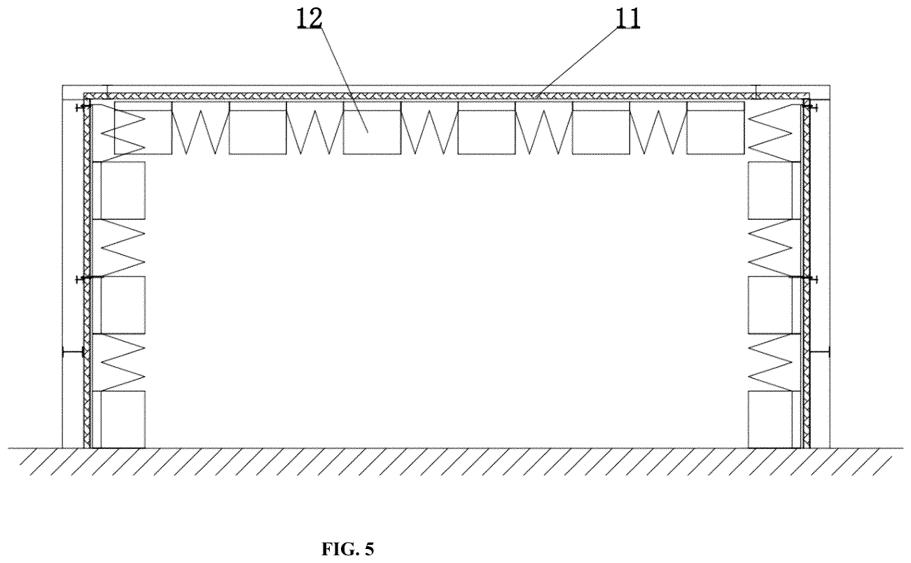

As shown in FIG. 1, FIG. 4 and FIG. 5, for the convenience of construction and application, both the hemi-anechoic chamber 1 and the run-through tunnel 2 may be of a rectangular structure, the hemi-anechoic chamber 1 is combined with the simulated track 3 (a rail reduced-scale model) through the run-through tunnel 2 of the rectangular structure, so as to achieve the purpose of providing a hemi-free field environment by the hemi-anechoic chamber 1 for the operation of the simulated track 3 and the reduced-scale train 32. The run-through tunnel 2 can be provided at the corner of the hemi-anechoic chamber 1 and attached to the short-edge side. At the moment, the simulated track 3 can be arranged in a diagonal direction of the hemi-anechoic chamber 1 when arranged, thus utilizing the internal space of the hemi-anechoic chamber 1 to the greatest extent, extending the laying length of the simulated track 3 under the same condition, and guaranteeing the maximum space utilization rate in a limited space. Alternatively, when the space is sufficient, the run-through tunnel 2 may be provided at any position on the short-edge side of the hemi-anechoic chamber 1, and the simulated track 3 can be arranged in a long edge direction of the hemi-anechoic chamber 1. It can be seen from the above that when the simulated track 3 is arranged in the long edge direction, the maximum braking distance is half the length of the long edge of the hemi-anechoic chamber 1, that is, the train decelerates immediately after passing through the midpoint. When the simulated track 3 is arranged in the diagonal line direction, the maximum braking distance is half the length of the diagonal line, which is longer than the long edge, and thus the corresponding maximum speed is higher, and the vibration and noise at higher speed can be tested.

The length, width and height of the run-through tunnel 2 are smaller than those of the hemi-anechoic chamber 1, that is, the run-through tunnel 2 is a structure with a smaller space which is constructed outside the hemi-anechoic chamber 1 and connected to the hemi-anechoic chamber 1. The dimension of the door opening 15 is reduced as much as possible to ensure that the reduced-scale train 32 and the simulated track 3 can pass smoothly. Therefore, the influence of the dimension of the door opening 15 on the test data can be reduced as much as possible, and the construction cost can also be saved.

A detachable wall 14 can be provided at the door opening 15, and a detachable structure is adopted for the simulated track 3 at the door opening 15. The detachable simulated track 3 can be arranged in the following way: single track slab has a length of 6 m, a width of 2.8 m and a thickness about 0.3 m to 0.5 m; in order to eliminate the boundary effect, three track slabs are required to be laid continuously in the hemi-anechoic chamber 1 in general, with steel rails 31 placed thereon and fasteners installed for assembling and laying. Excitation is exerted by manually knocking the steel rails 31 with a force hammer. Generally speaking, the amplitude and frequency spectrum of excitation force generated by the force hammer are relatively stable, which can be regarded as a standard excitation load. In this way, the vibration and noise reduction effect of different track structures can be evaluated by testing the vibration and noise of different track structures under the standard load produced by the force hammer. The detachable wall 14 has the same structure as the original wall of the hemi-anechoic chamber 1. The door opening 15 can be opened or closed with the detachable wall 14. The door opening 15 can be opened to facilitate the passing of the reduced-scale train 32 during rail transit related experiments (e.g., vibration and noise tests of the reduced-scale model), and the door opening 15 can be closed when only the tests inside the hemi-anechoic chamber 1 are carried out (e.g., real-scale tests of some track structures), and the sound absorption and insulation of the hemi-anechoic chamber 1 cannot be affected at the moment. In addition, wheels may also be provided at the bottom of the detachable wall 14 to facilitate the overall movement of the detachable wall 14, i.e., facilitating the opening and closing the door opening 15.

The hemi-anechoic chamber 1 may include an inner suite 12 and an outer suite 11 without rigid connection, and a rubber vibration isolator is provided between the inner suite 12 and the outer suite 11. The rubber vibration isolator is located under the floor of the inner suite 12 for supporting the inner suite 12. The above arrangement can effectively isolate the external solid sound transmission and further improve the accuracy of the test.

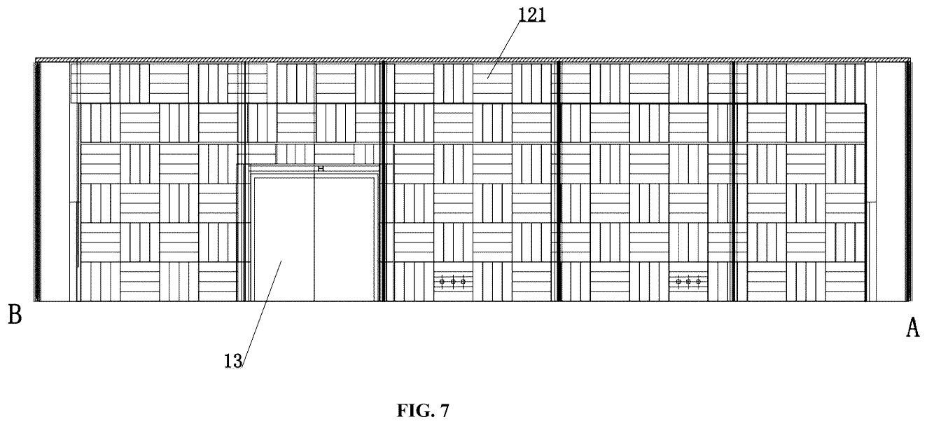

With reference to FIG. 7 to FIG. 11, the inner suite 12 may be formed by splicing metal sound insulation and absorption modules (including four walls and a roof, where a light box 16 is arranged on the roof). The metal sound insulation and absorption modules constitute a self-supporting structure of the inner suite 12 without an additional complicated steel frame supporting system. The metal sound insulation and absorption module may include a first wedge 121 and a connecting structure for connecting the first wedge 121, which are installed and fixed by a guide rail and a keel support. It should be noted that the installation structure and installation method can employ the prior art, the installation can be carried out according to the arrangement illustrated in FIG. 7 to FIG. 11, and will not be described in detail here. The outer suite 11 can be formed by splicing low-frequency sound absorption and insulation boards (including four walls and a roof). The low-frequency sound absorption and insulation boards can be relocated easily without affecting the acoustic characteristics. Moreover, the low-frequency sound absorption and insulation board takes into account both low-frequency sound absorption and sound insulation and is equivalent to some brick walls in sound insulation ability, but is relatively low in weight and do not require complex foundation designs.

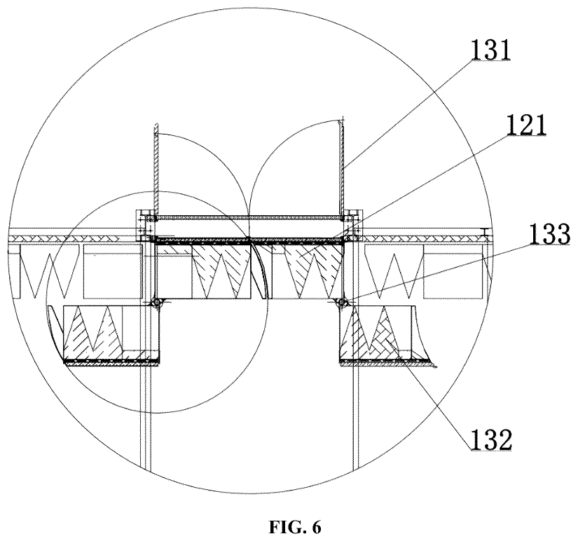

As shown in FIG. 1 and FIG. 6, the side face of the hemi-anechoic chamber 1 may be provided with a sound insulation door 13, which can be opened when needed to facilitate the passing, and can be closed during the test for effectively isolating noise. Meanwhile, the sound insulation door 13 is far away from the door opening 15 and close to the tail end of the simulated track 3, so as to reduce the influence of the sound insulation door 13 on the test process to the greatest extent. The sound insulation door 13 may be a single door or double door according to the passing equipment or personnel, for example, in FIG. 1, the AB face is provided with the double door, and the BC face is provided with the single door. The sound insulation door 13 can be opened/closed easily, and can stay at any angle. The sound insulation door 13 has no threshold (there is no any protrusion on the ground, and the ground is completely flush with the indoor and outdoor ground), so as to achieve barrier-free passing and facilitate the entry and exit of personnel and equipment.

The sound insulation door 13 may include an outer fireproof sound insulation door 131 and an inner sound insulation and absorption door 132, in which the fireproof sound insulation door 131 is opened from inside to outside, and the sound insulation and absorption door 132 is opened from outside to inside. A second wedge 141 may be provided on the inner surface of the sound insulation and absorption door 132, and a cavity between the second wedge 141 and the sound insulation and absorption door 132 is decorated by a skeleton and sound absorption boards to form an integrated sound insulation and absorption door 132. A floor support and a bridge floor are installed on the ground between the double-layer door (the outer fireproof sound insulation door 131 and the inner sound insulation and absorption door 132), and the metal sound absorption boards are installed on both sides and the top of the double-layer door to form a sound absorption sound-lock.

As for the specific installation form of the sound insulation and absorption door 132, a bushing may be provided at a door shaft of the sound insulation and absorption door 132, and the bushing is rotationally provided on a bushing support 133, thus making the sound insulation and absorption door 132 freely rotate around the bushing support 133. The top end of the bushing support 133 is fixed to the wall by a cantilever, and the bottom end of the bushing support 133 is fixed to the ground to form a vertical rotating supporting shaft capable of supporting the entire sound insulation and absorption door 132. The second wedge 141 may have the same shape as the first wedge 121. When the sound insulation and absorption door 132 is closed, the second wedge 141 and the first wedge 121 are flush with each other without interfering, and the sound insulation and absorption door 132 does not occupy the doorway passage space after being opened.

The system platform includes an air conditioning and ventilation module. The air conditioning and ventilation module is provided with two stages of mufflers, which are a first-stage muffler installed in an air conditioning room, and a second-stage muffler installed at the position where an air duct enters the anechoic room.

Specific embodiments of a system platform for evaluation and research and development of vibration and noise reduction technology for rail transit provided by the present disclosure are as follows:

The system platform includes: a hemi-anechoic chamber 1, a sound insulation door 13, a run-through tunnel 2, an air conditioning and ventilation module, a lighting module, a system monitoring module, etc.

The outline dimension of the hemi-anechoic chamber 1 is 22 m*12.5 m*6 m (length*width*height), which is the largest hemi-anechoic chamber 1 used to test and evaluate the vibration and noise reduction performance of track engineering in China at present. In order to meet the requirements of the system platform for the free field, metal sound absorption wedges (the first wedge 121 and the second wedge 141) with the longest service life and the best acoustic performance are used as the silencing module. The platform is designed, produced and installed based on the prefabricated concept. After installation, the tip-to-tip clearance dimension of the first wedge 121 is 20 m*10.4 m*5 m (length*width*height), the radius of the free field can reach about 8 meters in a long axis direction, and not less than 3 meters in a short axis direction; and the cut-off frequency of the hemi-anechoic chamber 1 is not higher than 63 Hz.

The hemi-anechoic chamber 1 is composed of CA special sound insulation modules, including an inner suite 12 and an outer suite 11. The inner suite 12 includes metal sound insulation and absorption modules and a sound insulation door 13, so as to effectively isolate external solid sound transmission.

In the structure of the inner suite 12, the metal sound insulation and absorption modules and special connectors constitute a self-supporting structure of the inner suite 12 without an additional complicated steel frame supporting system. The entire inner suite 12 is supported by a rubber vibration isolator arranged under the floor of the inner suite 12, no rigid connection exists between the inner suite 12 and the outer suite 11, and thus the external solid sound transmission can be effectively isolated. The metal sound insulation and absorption modules each include: a CA MW900 first wedge 121 (metal wedge) having a length of 900 mm, a cavity of 50 mm, a low-frequency sound absorption and insulation board, a CA special installation guide rail, and a keel support. The radius of the 63 Hz free field of the hemi-anechoic chamber 1 can be achieved: the radius in the long axis direction is >8 m, and the radius in the short axis direction is >3 m. A 40 mm hanger, channel steel, 40 mm angle iron and M6×10 screws are adopted at an installation node of the first wedge 121, and the CA special installation guide rail is installed on the keel support. The first wedge 121 is locked into a guide rail clamping groove with a locking bolt assembly at the bottom of the first wedge 121, and the bottom of the first wedge 121 is in an anti-skid design, thus preventing the first wedge 121 at the roof from slipping out of the guide rail.

In the structure of the outer suite 11, the outer suite 11 is composed of four walls and a roof which are made of CAIA45-L low-frequency sound absorption and insulation boards, the low-frequency sound absorption and insulation boards can be relocated easily without affecting the acoustic characteristics. Moreover, the low-frequency sound absorption and insulation board takes into account both low-frequency sound absorption and sound insulation and is equivalent to some brick walls in sound insulation ability, but is light in weight and does not require a complicated foundation design.

The sound insulation door 13 is a double-layer sound-lock rotary steel sound insulation door 13, and a second wedge 141 is installed on the inner surface of the sound insulation door 13. The passing clearance dimension of the sound insulation door 13 for equipment is: width×height 2,500 mm×2,600 mm, and the passing clearance dimension of the sound insulation door 13 for personnel is: width×height 800 mm×1,000 mm. A CAAD43 steel fireproof sound insulation door 131 is installed on the outer layer of the sound insulation door 13, which is opened from inside to outside and has a sound insulation capacity of 43 dB. A CAAD40 steel sound insulation and absorption door 132 is installed on the inner layer of the sound insulation door 13, which is opened from outside to inside and has a sound insulation capacity of 40 dB. The sound insulation door 13 can be opened/closed easily, and can stay at any angle. The sound insulation door 13 has no threshold (there is no any protrusion on the ground, and the ground is completely flush with the indoor and outdoor ground), so as to achieve barrier-free passing and facilitate the entry and exit of personnel and equipment. A floor support and a bridge floor are installed on the ground between the double-layer door, and metal sound absorption boards are installed on both sides and the top of the double-layer door to form a sound absorption sound-lock.

The door shaft of the sound insulation and absorption door 132 is arranged on the bushing support 133 (rather than on the wall), the upper end of the bushing support 133 is fixed to the wall, and the lower end of the bushing support 133 is fixed to the ground through an anchor, a central shaft of the bushing support 133 is in rolling connection with the door shaft through an axle bearing, and a cavity between the sound insulation door 13 and the second wedge 141 is decorated by a skeleton and sound absorption boards to form an integrated sound insulation and absorption door 132. The second wedge 141 is flush with the first wedge 121 when the sound insulation door 13 is closed, and has the same shape as the first wedge 121. The opening trajectory and rotation radius of the sound insulation door 13 do not interfere with each other. The sound insulation door 13 is completed by a three-dimensional design and rotates 180 degrees or 90 degrees after being opened, thus not occupying the doorway passage space.

The run-through tunnel 2 is equivalent to a large muffler, which is used to reduce the external ventilation noise and to provide a space for the passing reduced-scale train 32. A detachable wall 14 is provided at the door opening 15. When the reduced-scale train 32 is required to pass through, the detachable wall 14 and the second wedge 141 are disassembled to facilitate the passing of the reduced-scale train 32. When the reduced-scale train 32 does not need to pass through, the detachable wall 14 and the second wedge 141 are restored, thus not affecting the sound absorption and insulation of the hemi-anechoic chamber 1. The dimension of the run-through tunnel 2 is 5.25 m*5.8 m*3 m, and the sound insulation capacity is about 40 dB. The hemi-anechoic chamber 1 is combined with the simulated track 3 through the run-through tunnel 2, and thus the purpose of providing a free field boundary by the hemi-anechoic chamber 1 for the reduced-scale model is achieved.

The air conditioning and ventilation module includes cooling/heating units, a cooling fan unit, an electric heating unit, a control system, a temperature sensor, an air duct and a tuyere, and a ventilation muffler. The quantity of indoor ventilation is designed according to six cycles per hour, the indoor net volume is 1,000 m³, the maximum circulating air volume is 6,000 m³/h. Cooling or heating can be turned on according to seasons to regulate indoor temperature to (20 to 26) ° C., relative humidity to (30 to 90)%, and fresh air ventilation rate to not less than 5 times/hour.

The operation mode of the air conditioning and ventilation module is as follows: 1) when there is no heat generated by the equipment running in the hemi-anechoic chamber 1, a small amount of fresh air is added for a closed cycle mode to satisfy the measurement requirements and an environment for a preparation stage. 2) When the outdoor temperature is between 20° C. and 25° C., a full fresh air mode is employed, the cooling and heating units are all turned off, and the outdoor air is used to regulate the indoor temperature. 3) When the outdoor temperature is higher than 25° C., the cooling fan unit is turned on, the indoor temperature is mainly regulated by circulating air, and fresh air and air exhaust can be turned on as required. 4) When the outdoor temperature is lower than 20° C., the electric heating unit is turned on, the indoor temperature is mainly adjusted by circulating air, and fresh air and air exhaust can be turned on as required. The above operation states are automatically achieved through the control system and the temperature sensor. The control system can automatically control the air volume and cooling (heating) capacity of the system according to the indoor temperature, so as to achieve the purpose of energy saving and temperature control. All controls are displayed through a touch screen and animation, so as to achieve man-machine interaction. The air conditioning unit consists of a mixing section, a cooling coil section and a fan section.

Two stages of mufflers are respectively installed at air supply and return ducts of the ventilation muffler: the first-stage muffler is installed in the air conditioning room, the model is a CAVS muffler, and the dimension is 800 mm×800 mm×2,000 mm; and the second-stage muffler is installed at the position where the air duct enters the hemi-anechoic chamber 1, the model is a CAVSF muffler, the dimension is 800 mm×800 mm×2,000 mm.

The lighting module includes lamps, an emergency alarm system, emergency lighting, and an integrated power distribution interface.

Low-noise, high-brightness and energy-saving LED lamps are used as lighting lamps, and by using special sound absorption installation brackets, the LED lamps are respectively installed at the top of the hemi-anechoic chamber 1, and arranged in a decentralized manner of 6 rows×3 columns. Under the condition that indoor lamps are fully turned on, the indoor illumination is not less than 500 lux (measured at 1.0 m away from the ground grid). The lamps are divided into high-brightness and ordinary groups and are controlled in groups. The service life of the LED lamp is not less than 5,000 hours.

The outline dimension of the lamp is small and has a diameter of 30 mm, which has less interference to the free field and low noise; and after the lamps are installed, the hemi-anechoic chamber 1 can still satisfy the requirements of free field accuracy and background noise stipulated by ISO3745. The emergency alarm system and a lighting system with an emergency power supply are arranged above an access door of the hemi-anechoic chamber 1, which can operate normally when the whole power supply is cut off due to power failure or other faults of the hemi-anechoic chamber 1, and can operate continuously for at least one hour. A safety light is provided outside a service door to indicate an operating state in the hemi-anechoic chamber 1. All lighting lamps do not affect the free sound field characteristics of the hemi-anechoic chamber 1, and much less generate noise.

Various power distribution interfaces in the hemi-anechoic chamber 1 are integrated on a workpiece (a variable-frequency power supply is introduced, including three-phase and single-phase interfaces), and a mains power supply interface is provided. Power cable penetrating holes are all silenced. In addition to single-phase 30 kVA instruments and lighting power, sample junction boxes are provided indoors, including two 10A three-pole sockets and two 10A two-pole sockets, etc. The sockets are in a floor socket design, and pipelines are embedded when the floor is poured, all of which are earthed. Two 110V, 220V and 380V main sockets are provided, and a power distribution box and an air switch are installed in a control room. Lightning protection should comply with the provisions of GB50057, and the internal metal cable raceways, pipelines and metal structures shall be in equipotential bonding and earthed.

The system monitoring module includes a fire alarm system and a monitoring system.

The fire alarm system is provided with two fire detectors: a temperature detector and a smoke detector, and an automatic fire alarm system is provided to be linked with a fire extinguishing system. The automatic fire alarm system includes two Honeywell smoke alarms. The Honeywell XLS smoke alarm has five sensitivities for setting, and has a minimum protection radius of 4.55 m when installed on the ceiling. The fire extinguishing system in the room includes portable dry powder extinguishers, and MF ABC4 ammonium phosphate dry powder extinguishers are employed, each of which is 23 kg, and has a maximum protection distance of 20 m. Two fire extinguishers are provided at the door of the room.

The monitoring system is provided with four cameras, two of the cameras each are equipped with pa an/tilt head and an automatic zoom lens, with magnification of the electric optical zoom lens of 10× to 50×, and the other two of the cameras each are equipped with a wide-angle lens or a manual zoom lens, thus adapting to a low illumination environment. The pan/tilt head can achieve 270-degree plane rotation and adjust a visual angle up and down. One liquid crystal display and one controller are installed outdoors for switching pictures of multiple cameras, and video data are stored through a recorder of the controller. A two-way intercom system is provided between the hemi-anechoic chamber 1 and the control room to achieve the communication in different spaces. Internal and external communication facilities, omni-directional video surveillance and a distress alarm system are also provided.

Several examples are used for illustration of the principles and implementation methods of the present disclosure. The description of the embodiments is merely used to help illustrate the method and its core principles of the present disclosure. In addition, those of ordinary skill in the art can make various modifications in terms of specific embodiments and scope of application in accordance with the teachings of the present disclosure. In conclusion, the content of this specification shall not be construed as a limitation to the present disclosure.

1. A system platform for evaluation and research and development of vibration and noise reduction technology for rail transit, comprising a hemi-anechoic chamber, a run-through tunnel, a simulated track, and a reduced-scale train running on the simulated track, wherein the run-through tunnel is enclosed by sound insulation and absorption boards; the side wall of the hemi-anechoic chamber is provided with a door opening; the exit of the run-through tunnel communicates with the door opening, and the entrance of the run-through tunnel is arranged at the end part, away from the hemi-anechoic chamber, of the run-through tunnel; and the simulated track is continuously arranged into the hemi-anechoic chamber from the outside of the run-through tunnel via the entrance, the exit and the door opening; and a simulated hemi-free space is provided in the hemi-anechoic chamber, and the vibration and noise of the reduced-scale train when passing through the simulated hemi-free space are tested.

2. The system platform for evaluation and research and development of vibration and noise reduction technology for rail transit according to claim 1, wherein the hemi-anechoic chamber and the run-through tunnel are both of a rectangular structure, the run-through tunnel is arranged on the short-edge side at the corner of the hemi-anechoic chamber, and the simulated track is arranged in a diagonal direction of the hemi-anechoic chamber, or the run-through tunnel is arranged on the short-edge side of the hemi-anechoic chamber, and the simulated track is arranged in a long edge direction of the hemi-anechoic chamber.

3. The system platform for evaluation and research and development of vibration and noise reduction technology for rail transit according to claim 2, wherein the length, width and height of the run-through tunnel are smaller than those of the hemi-anechoic chamber.

4. The system platform for evaluation and research and development of vibration and noise reduction technology for rail transit according to claim 3, wherein a detachable wall is provided at the door opening, and the detachable wall has the same structure as the original wall of the hemi-anechoic chamber; wheels are arranged at the bottom of the detachable wall; a detachable structure is adopted for the simulated track at the door opening employs; and the original function of the hemi-anechoic chamber is able to be recovered by disassembling the simulated track and installing the detachable wall.

5. The system platform for evaluation and research and development of vibration and noise reduction technology for rail transit according to claim 1, wherein the hemi-anechoic chamber comprises an inner suite and an outer suite without rigid connection, a rubber vibration isolator is provided between the inner suite and the outer suite, and the rubber vibration isolator is located under the floor of the inner suite for supporting the inner suite.

6. The system platform for evaluation and research and development of vibration and noise reduction technology for rail transit according to claim 5, wherein the inner suite is formed by splicing metal sound insulation and absorption modules, the metal sound insulation and absorption modules constitute a self-supporting structure of the inner suite, the metal sound insulation and absorption modules each comprise a first wedge and a connecting structure for connecting the first wedge, and the outer suite is formed by splicing low-frequency sound absorption and insulation boards.

7. The system platform for evaluation and research and development of vibration and noise reduction technology for rail transit according to claim 6, wherein the side face of the hemi-anechoic chamber is provided with a sound insulation door, and the sound insulation door is far away from the door opening and close to the tail end of the simulated track.

8. The system platform for evaluation and research and development of vibration and noise reduction technology for rail transit according to claim 7, wherein the sound insulation door comprises an outer fireproof sound insulation door and an inner sound insulation sound absorption door; the fireproof sound insulation door is opened from inside to outside, the sound insulation and absorption door is opened from outside to inside, and a second wedge is arranged on the inner surface of the sound insulation and absorption door, and a cavity between the second wedge and the sound insulation and absorption door is decorated by a skeleton and a sound absorption board, so as to form an integrated sound insulation and absorption door.

9. The system platform for evaluation and research and development of vibration and noise reduction technology for rail transit according to claim 8, wherein the sound insulation and absorption door is provided with a bushing at a door shaft, the bushing is rotationally arranged on a bushing support, the top end of the bushing support is fixed to a wall through a cantilever, and the bottom end of the bushing support is fixed to the ground; the second wedge has the same shape as the first wedge, and when the sound insulation and absorption door is closed, the second wedge and the first wedge are flush with each other without interfering.

10. The system platform for evaluation and research and development of vibration and noise reduction technology for rail transit according to claim 1, comprising an air conditioning and ventilation module, wherein the air conditioning and ventilation module is provided with two stages of mufflers, comprising a first-stage muffler installed in an air conditioning chamber, and a second-stage muffler installed at the position where an air duct enters the anechoic chamber.

11. The system platform for evaluation and research and development of vibration and noise reduction technology for rail transit according to claim 2, wherein the hemi-anechoic chamber comprises an inner suite and an outer suite without rigid connection, a rubber vibration isolator is provided between the inner suite and the outer suite, and the rubber vibration isolator is located under the floor of the inner suite for supporting the inner suite.

12. The system platform for evaluation and research and development of vibration and noise reduction technology for rail transit according to claim 3, wherein the hemi-anechoic chamber comprises an inner suite and an outer suite without rigid connection, a rubber vibration isolator is provided between the inner suite and the outer suite, and the rubber vibration isolator is located under the floor of the inner suite for supporting the inner suite.

13. The system platform for evaluation and research and development of vibration and noise reduction technology for rail transit according to claim 4, wherein the hemi-anechoic chamber comprises an inner suite and an outer suite without rigid connection, a rubber vibration isolator is provided between the inner suite and the outer suite, and the rubber vibration isolator is located under the floor of the inner suite for supporting the inner suite.

14. The system platform for evaluation and research and development of vibration and noise reduction technology for rail transit according to claim 11, wherein the inner suite is formed by splicing metal sound insulation and absorption modules, the metal sound insulation and absorption modules constitute a self-supporting structure of the inner suite, the metal sound insulation and absorption modules each comprise a first wedge and a connecting structure for connecting the first wedge, and the outer suite is formed by splicing low-frequency sound absorption and insulation boards.

15. The system platform for evaluation and research and development of vibration and noise reduction technology for rail transit according to claim 12, wherein the inner suite is formed by splicing metal sound insulation and absorption modules, the metal sound insulation and absorption modules constitute a self-supporting structure of the inner suite, the metal sound insulation and absorption modules each comprise a first wedge and a connecting structure for connecting the first wedge, and the outer suite is formed by splicing low-frequency sound absorption and insulation boards.

16. The system platform for evaluation and research and development of vibration and noise reduction technology for rail transit according to claim 13, wherein the inner suite is formed by splicing metal sound insulation and absorption modules, the metal sound insulation and absorption modules constitute a self-supporting structure of the inner suite, the metal sound insulation and absorption modules each comprise a first wedge and a connecting structure for connecting the first wedge, and the outer suite is formed by splicing low-frequency sound absorption and insulation boards.

17. The system platform for evaluation and research and development of vibration and noise reduction technology for rail transit according to claim 14, wherein the side face of the hemi-anechoic chamber is provided with a sound insulation door, and the sound insulation door is far away from the door opening and close to the tail end of the simulated track.

18. The system platform for evaluation and research and development of vibration and noise reduction technology for rail transit according to claim 15, wherein the side face of the hemi-anechoic chamber is provided with a sound insulation door, and the sound insulation door is far away from the door opening and close to the tail end of the simulated track.

19. The system platform for evaluation and research and development of vibration and noise reduction technology for rail transit according to claim 16, wherein the side face of the hemi-anechoic chamber is provided with a sound insulation door, and the sound insulation door is far away from the door opening and close to the tail end of the simulated track.

20. The system platform for evaluation and research and development of vibration and noise reduction technology for rail transit according to claim 17, wherein the sound insulation door comprises an outer fireproof sound insulation door and an inner sound insulation sound absorption door; the fireproof sound insulation door is opened from inside to outside, the sound insulation and absorption door is opened from outside to inside, and a second wedge is arranged on the inner surface of the sound insulation and absorption door, and a cavity between the second wedge and the sound insulation and absorption door is decorated by a skeleton and a sound absorption board, so as to form an integrated sound insulation and absorption door.
